(19) United States
(12) Patent Application Publication
(10) Pub. No.: US 2021/0358784 A1
(43) Pub. Date: Nov. 18, 2021

(54) FAULT MONITORING SYSTEM AND METHOD FOR SEMICONDUCTOR MANUFACTURING PROCESS

(71) Applicant: CHANGXIN MEMORY TECHNOLOGIES, INC., Hefei City (CN)

(72) Inventor: Huan-Cheng Li, Hefei (CN)

(21) Appl. No.: 17/386,450

(22) Filed: Jul. 27, 2021

Related U.S. Application Data
(63) Continuation of application No. PCT/CN2021/088629, filed on Apr. 21, 2021.

(30) Foreign Application Priority Data
Apr. 21, 2020 (CN) 202010316832.X

(51) Int. Cl. H01L 21/67; H01L 21/66; H01L 21/677; G05B 23/02

(52) U.S. Cl. CPC H01L 21/67253; G05B 23/0235; H01L 21/677; H01L 22/14

(57) ABSTRACT

A fault monitoring system and method for a semiconductor manufacturing process are involved. The method for monitoring the fault includes: acquiring a handling completion record and a goods arrival at Equipment (EQP) record from a Manufacturing Execution System (MES); determining whether the handling completion record corresponds to the goods arrival at EQP record by comparing the acquired handling completion record and goods arrival at EQP record; and when the handling completion record does not correspond to the goods arrival at EQP record, generating exception reporting information and sent the exception reporting information to a monitoring platform. No operation after goods arrival at EQP can be monitored automatically.

### CROSS-REFERENCE TO RELATED APPLICATIONS

This application is a continuation of International Application No. PCT/CN2021/088629, filed on Apr. 21, 2021, which is based upon and claims priority to Chinese patent application No. 202010316832.X, filed on Apr. 21, 2020 and entitled “Fault Monitoring System and Method for Semiconductor Manufacturing Process”. The contents of International Application No. PCT/CN2021/088629 and Chinese patent application No. 202010316832.X are incorporated herein by reference in their entireties.

### TECHNICAL FIELD

The disclosure relates to the technical field of semiconductor manufacturing, and more particularly, to a fault monitoring system and method for a semiconductor manufacturing process.

### BACKGROUND

In a manufacturing process of a semiconductor device, a Front Opening Unified Pod (FOUP) is generally used to protect, convey, and store a wafer, to avoid the contamination of the wafer by tiny dust in the external environment during the conveyance of the wafer between each piece of production Equipment (EQP), which may affect the yield rate. Currently, an Automated Material Handling System (AMHS) is generally used to implement the conveyance to improve the production efficiency and the safety.

A current conveying process mainly includes following operations. When a FOUP including a wafer is to be handled, a Manufacturing Execution System (MES) sends a handling request to the AMHS. The AMHS assigns its own Overhead Hoist Transfer (OHT) to handle the specified FOUP to the destination EQP, conveys the FOUP to a position above the EQP (semiconductor production EQP), and places the FOUP at a Load Port of the EQP. The Load Port reads and reports a FOUP Identity document (ID) to an EQP Automation Program (EAP). The EAP reports the goods arrival at EQP as well as the FOUP ID read by the EQP to a Tool Control System (TCS). The TCS generates a goods arrival at EQP record and a FOUP ID reading record according to the reported EQP and the FOUP ID read by the EQP, and sends them to the MES, such that the MES updates a goods arrival at EQP state to a database according to the received goods arrival at EQP record and FOUP ID reading record, and then performs the subsequent production flows.

However, after the MES sends a handling task to the AMHS and the FOUP is handled to the EQP by the OHT, there may often be such a problem that the EQP does not read the FOUP ID and report the FOUP ID to the TCS and the EAP, resulting in no operation after goods arrival at EQP, which seriously affects the production efficiency.

### SUMMARY

An aspect of the disclosure provides a method for monitoring a default in a semiconductor manufacturing process. The method includes the following operations.

A handling completion record and a goods arrival at EQP record are acquired from an MES.

It is determined whether the handling completion record corresponds to the goods arrival at EQP record by comparing the acquired handling completion record and goods arrival at EQP record.

When the handling completion record does not correspond to the goods arrival at EQP record, exception reporting information is generated and sent to a monitoring platform.

Another aspect of the disclosure also provides a system for monitoring a default in a semiconductor manufacturing process. The system includes a storage module and a monitoring module.

The storage module is configured to store a handling completion record and a goods arrival at EQP record.

The monitoring module is in communication connection with the storage module, and is configured to acquire the handling completion record and the goods arrival at EQP record from an MES, determine whether the handling completion record corresponds to the goods arrival at EQP record by comparing the acquired handling completion record and goods arrival at EQP record, and when the handling completion record does not correspond to the goods arrival at EQP record, generate send the exception reporting information and send the exception reporting information to a monitoring platform.

Details of one or more embodiments of the disclosure will be put forward in the following accompanying drawings and descriptions. Other features, objectives, and advantages of the disclosure will become clearer in the description, the accompanying drawings, and the claims.

### BRIEF DESCRIPTION OF THE DRAWINGS

In order to describe and illustrate the embodiments of the disclosure better, references can be made to one or more accompanying drawings. However, appended details or examples for describing the accompanying drawings should not be considered as the limitation of the scope of the creative invention, embodiments currently described, or preferred manners of the disclosure.

FIG. 1 is a flowchart of a method for monitoring a fault in a semiconductor manufacturing process according to an embodiment of the disclosure.

FIG. 2 is a flowchart of another method for monitoring a fault in a semiconductor manufacturing process according to an embodiment of the disclosure.

FIG. 3 is a schematic diagram of an electrical structure of a system for monitoring a fault in a semiconductor manufacturing process according to the disclosure.

FIG. 4 is a schematic diagram of another electrical structure of a system for monitoring a fault in a semiconductor manufacturing process according to the disclosure.

FIG. 5 is a schematic diagram of an interactive relationship between a system for monitoring a fault in a semiconductor manufacturing process and another system according to the disclosure.

### DETAILED DESCRIPTION

In order to make the objectives, features, and advantages of the disclosure clearer and easier to understand, specific implementations of the disclosure will be described below in detail in conjunction with the accompanying drawings. Many specific details are described in the following descriptions to facilitate a full understanding of the disclosure. However, the disclosure may be implemented in many other manners different from those described herein, those skilled in the art may make similar improvements without departing from the essence of the disclosure, and thus the disclosure is not limited by the specific implementations disclosed below.

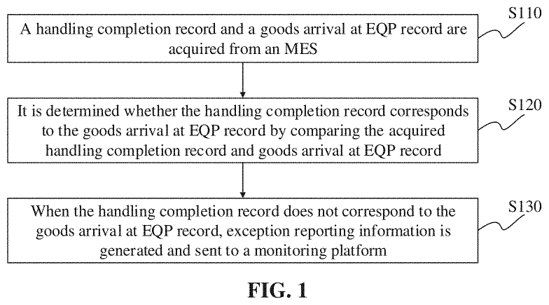

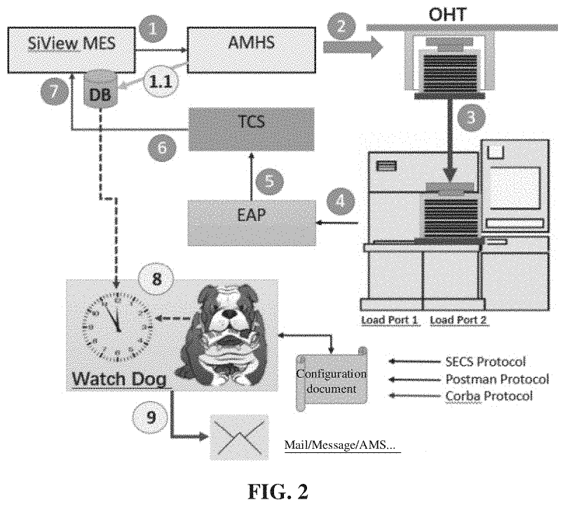

Referring to FIG. 1 and FIG. 2, an embodiment of the disclosure provides a method for monitoring a fault in a semiconductor manufacturing process. The method includes steps S110 to S130.

In S110, a handling completion record and a goods arrival at EQP record are acquired from an MES.

In the embodiment, the handling completion record is generated and reported to the MES after an AMHS performs a corresponding handling operation on a material responsive to a handling request from the MES. In general, the handling completion record includes at least an ID of destination EQP and an ID of the material in successful handling. For an actual case that a FOUP is used to protect and convey a wafer, the ID of the material may specifically be a FOUP ID. Furthermore, an actual handling process further includes handling the FOUP to a Load Port of the destination EQP. Generally, each piece of EQP includes multiple corresponding Load Ports. In another embodiment, the handling completion record may further include a Load Port ID of the destination EQP.

The destination EQP reports the goods arrival at EQP record to a TCS after receiving and reading the handled material, and then the TCS reports the goods arrival at EQP record to the MES. The goods arrival at EQP record includes at least an ID of the material read by the EQP and an ID of the EQP. In the embodiment, the goods arrival at EQP record includes the EQP ID and a FOUP ID reported by the EQP. In another embodiment, the goods arrival at EQP record may further include a specific Load Port ID of the destination EQP.

In a specific manufacturing process, when a FOUP including a wafer is to be handled, the MES sends a handling task to the AMHS. The AMHS assigns its own OHT to handle the specified FOUP to the destination EQP, conveys the FOUP to a position above the EQP (semiconductor production EQP), places the FOUP at a Load Port of the EQP, and then generates a handling completion record after successful handling, the handling completion record includes a destination EQP ID, a Load Port ID, and a FOUP ID. The Load Port reads and reports the FOUP ID to an EAP. The EAP reports the EQP that performs a reporting operation and the FOUP ID read by the EQP to the TCS. The TCS generates a goods arrival at EQP record according to the reported EQP ID and the FOUP ID read by the EQP, and sends the goods arrival at EQP record to the MES, such that the MES updates a goods arrival at EQP state to a database according to the received goods arrival at EQP record and stores the goods arrival at EQP record.

It should be understood that the EQP ID may be an EQP number, an EQP type, or other information of the EQP. In the embodiment, the EQP number is used as the EQP ID, and thus the EQP ID may be named according to a process characteristic. However, each piece of EQP corresponds to only one EQP ID for the convenience of management. In addition, the method for monitoring the fault may be implemented by the monitoring program “watchdog”. In some other embodiments, the handling completion record and the goods arrival at EQP record may further include some other information, such as the material state information and the handling time information. Herein the material state information is configured to represent a current production state of the material, for example, the material is currently to be processed or under processing.

In S120, it is determined whether the handling completion record corresponds to the goods arrival at EQP record by comparing the acquired handling completion record and goods arrival at EQP record.

In the embodiment, the handling completion record and the goods arrival at EQP record are compared. When the ID of the destination EQP involved in successful handling in the handling completion record is the same as the EQP ID in the goods arrival at EQP record, and the ID of the handled material is the same as the ID of the material read by the EQP, it is determined that the handling completion record corresponds to the goods arrival at EQP record. Otherwise, it is determined that the compared handling completion record does not correspond to the goods arrival at EQP record.

Specifically, determining whether the handling completion record corresponds to the goods arrival at EQP record one by one by comparing the acquired handling completion record and goods arrival at EQP record is mainly determining whether there is a respective matched goods arrival at EQP record for each handling completion record according to the information of FOUPs in the handling completion record and the goods arrival at EQP record, the information of the FOUP includes the specific position information of the FOUPs, the production state information of the FOUPs, and the FOUP IDs. When there is no goods arrival at EQP record matched with one of the handling completion records can be found, it is determined that the EQP corresponding to the handling completion record completes the handling but has not updated the information of the FOUP, that is, the EQP has not performed a reading operation currently.

In S130, when the handling completion record does not correspond to the goods arrival at EQP record, exception reporting information is generated and sent to a monitoring platform.

In the method for monitoring the fault provided in the disclosure, the handling completion record and the goods arrival at EQP record are compared, and when the handling completion record does not correspond to the goods arrival at EQP record, it is determined that an exception occurs to the manufacturing process, and the exception reporting information is generated and sent to the monitoring platform, so that no operation after goods arrival at EQP may be monitored automatically to find the problem of no reading operation after the goods arrives at the EQP as soon as possible, thereby the production efficiency can be ensured.

In an embodiment, the operation that the handling completion record and the goods arrival at EQP record are acquired from the MES includes the following operation.

The handling completion record is acquired from a first submodule of a storage module of the MES, and the goods arrival at EQP record is acquired from a second submodule of the storage module of the MES.

It should be understood that, in the embodiment, the storage module of the MES includes the first submodule and the second submodule, the first submodule and the second submodule are configured to store the handling completion record and the goods arrival at EQP record respectively. The handling completion record and the goods arrival at EQP record are stored and acquired separately, so that the data may be easily read and compared, which facilitate speeding up the processing process.

Due to a time difference between procedures, the handling completion record is updated earlier than the goods arrival at EQP record. Therefore, in an embodiment, acquiring the handling completion record and the goods arrival at EQP record from the MES further includes the following operations.

The triggering information sent by the MES is received. Herein the triggering information is generated by the MES after the MES receives the handling completion record.

The handling completion record is acquired from the MES according to the triggering information, and a first timing is started.

When the duration of the first timing reaches a first preset time interval, the goods arrival at EQP record is acquired from the MES.

In the embodiment, the triggering information is generated by the MES after updating the handling completion record to trigger “watchdog” to be started and acquire the handling completion record from the MES. Meanwhile, the first timing is performed, and when the duration of the first timing reaches the first preset time interval, the goods arrival at EQP record is acquired from the MES, thereby avoiding a false determination caused by untimely updating by the MES. It should be noted that the step of acquiring the handling completion record from the MES may be completed before the step of acquiring the goods arrival at EQP record, or may be executed at the same time with the step of acquiring the goods arrival at EQP record. No limits are made thereto in the embodiment.

In an embodiment, the operation that the exception reporting information is generated and sent to the monitoring platform when the handling completion record does not correspond to the goods arrival at EQP record includes the following operations.

When the handling completion record does not correspond to the goods arrival at EQP record, acquiring the goods arrival at EQP is retried after a second preset time interval, and it is determined whether the handling completion record corresponds to the goods arrival at EQP record until a number of retries reaches a preset number of retries.

When a result of the last determination shows that the handling completion record does not correspond to the goods arrival at EQP record, the exception reporting information is generated and sent to the monitoring platform.

In the embodiment, when the handling completion record does not correspond to the goods arrival at EQP record, the fault monitoring system determines the corresponding EQP that completes material handling but does not update a position or state of the material and the Load Port of the EQP, counts an “inconsistency” of the position or state of the material once, determines the count of the “inconsistency” as the number of retries, and determines whether the number of retries is less than the preset number of retries. If so, the second timing is performed, and when the duration of the second timing reaches the second preset time interval, the step of acquiring the goods arrival at EQP record from the second submodule of the storage module of the MES is re-executed. Otherwise, the exception reporting information is generated and sent to the monitoring platform.

After determining the corresponding EQP that completes handling but does not update the state and the Load Port of the EQP, considering that the time for the EQP to read and report the FOUP ID is much less than an interval between two handling tasks, the “watchdog” may, after it is determined that the handling completion record does not correspond to the goods arrival at EQP record one by one, repeatedly acquire the goods arrival at EQP record from the MES at a second preset time interval to confirm whether the problem of no operation after goods arrives at EQP exists as soon as possible and, when determining that the problem of no operation after goods arrival at EQP exists, notify a staff to solve the problem timely. In addition, acquiring the goods arrival at EQP record from the MES only at the second preset time interval may reduce a transmitted data volume and accelerate a determination process.

In an embodiment, a value of the second time interval ranges from 5 to 15 seconds. It should be understood that the value of the second time interval ranges from 5 to 15 seconds, so that the EQP has enough time to read and report the FOUP ID, a false determination caused by excessively short time and/or a relatively low reading speed of the EQP may be avoided. Furthermore, the problem of no operation after goods arrival at EQP cannot be found timely due to the excessively long time interval is also avoided. In the embodiment, the second time interval is preferably 8, 10, and 12 seconds.

In an embodiment, a value of the preset number of retries ranges from 3 to 8. It should be understood that the handling completion record is generated earlier than the goods arrival at EQP record, so the EQP that works normally may be in the process of reading or reporting the FOUP ID when the handling completion record is read. Thus it may not be determined whether there is no operation after goods arrival at EQP according to one comparison result. In the embodiment, after it is determined that the handling completion record does not correspond to the goods arrival at EQP record one by one, the goods arrival at EQP record may be acquired for many times according to the second time interval, and the “inconsistency” of the position or state of the material is counted continuously, i.e., when the number of retries reaches the preset number of retries, the exception reporting information is sent to avoid a false determination. In the embodiment, the preset number of retries is preferably set to 4, 5, and 6.

In an embodiment, the exception reporting information is sent to the monitoring platform by a mail, a message, or a notification of an Alarm Management System (AMS) to facilitate the staff at the monitoring platform to acquire the specific content of the exception reporting information and to quickly troubleshoot the fault. Furthermore, an alarming device may further be arranged at the monitoring platform, such as an alarm lamp flashing or an alarm horn beeping, to enable the staff at the monitoring platform to acquire the exception information timely. In the embodiment, the exception reporting information may include the EQP ID, the Load Port ID, and the FOUP ID, and in addition, may further include FOUP handling completion time and current state information of the material.

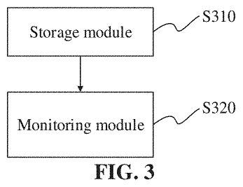

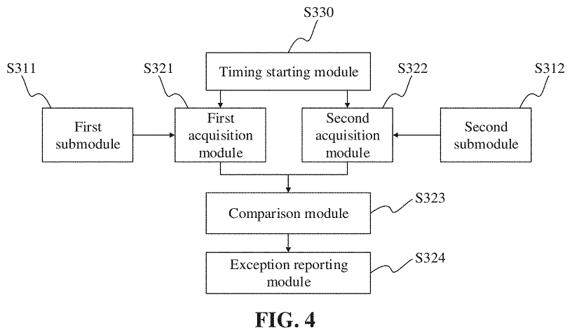

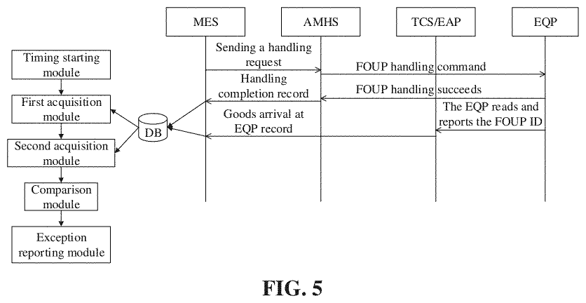

Referring to FIG. 3, FIG. 4, and FIG. 5, based on the same inventive concept, an embodiment of the disclosure further provides a system for monitoring the fault in a semiconductor manufacturing process. The system for monitoring the fault includes a storage module 310 and a monitoring module 320.

The storage module 310 is configured to store a handling completion record and a goods arrival at EQP record.

The monitoring module 320 is in communication connection with the storage module 310, and is configured to acquire the handling completion record and the goods arrival at EQP record from an MES, determine whether the handling completion record corresponds to the goods arrival at EQP record by comparing the acquired handling completion record and goods arrival at EQP record, and when the handling completion record does not correspond to the goods arrival at EQP record, generate exception reporting information and send the exception reporting information to a monitoring platform.

In the embodiment, the handling completion record is generated and reported to an MES after an AMHS performs a corresponding handling operation on a material responsive to a handling request from the MES. In general, the handling completion record includes at least an ID of destination EQP and an ID of the material in successful handling. For the AMHS that actually uses a FOUP to protect and convey a wafer, the ID of the material may specifically be a FOUP ID. Furthermore, an actual handling process further includes handling the FOUP to a Load Port of the destination EQP. Generally, each piece of EQP includes multiple corresponding Load Ports. In another embodiment, the handling completion record may further include a Load Port ID of the destination EQP.

The destination EQP reports the goods arrival at EQP record to a TCS after receiving and reading the handled material, and then the TCS reports the goods arrival at EQP record to the MES. The goods arrival at EQP record includes at least an ID of the material read by the EQP and an ID of the EQP. Specifically, the goods arrival at EQP record includes the EQP ID and a FOUP ID reported by the EQP. In another embodiment, the goods arrival at EQP record may further include a specific Load Port ID of the destination EQP.

In the specific manufacturing system, the storage module 310 is arranged in the MES. When a FOUP including a wafer is to be handled, the MES sends a handling task to the AMHS. The AMHS assigns its own OHT to handle the specified FOUP to the destination EQP, conveys the FOUP to a position above the EQP (semiconductor production EQP), places the FOUP at a Load Port of the EQP, and then generates a handling completion record after the successful handling, the handling completion record includes a destination EQP ID, a Load Port ID, and a FOUP ID. The Load Port reads and reports the FOUP ID to an EAP. The EAP reports the EQP that performs a reporting operation and the FOUP ID read by the EQP to the TCS. The TCS generates a goods arrival at EQP record according to the reported EQP and the FOUP ID read by the EQP, and sends the goods arrival at EQP record to the MES, such that the MES updates a goods arrival at EQP state to a database according to the received goods arrival at EQP record and stores the goods arrival at EQP record in the storage module 310.

It should be understood that the EQP ID may specifically be an EQP number, an EQP type, and other information of the EQP. In the embodiment, the EQP number is used as the EQP ID, and thus the EQP ID may be named according to a process characteristic. However, each piece of EQP corresponds to only one EQP ID for the convenience of management. In addition, the monitoring module 320 may be a monitoring program “watchdog”. In some other embodiments, the handling completion record and the goods arrival at EQP may further include some other information, such as material state information and handling time information. Herein the material state information is configured to represent a current production state of the material, for example, the material is currently to be processed or under processing.

In an embodiment, the storage module 310 includes a first submodule 311 and a second submodule 312. The first submodule 311 is configured to store the handling completion record. The second submodule 312 is configured to store the goods arrival at EQP record. It should be understood that the handling completion record and the goods arrival at EQP record are stored and acquired separately, so that the data may be easily read and compared, which facilitate speeding up the processing process.

In an embodiment, the monitoring module 320 includes a first acquisition module 321, a second acquisition module 322, a comparison module 323, and an exception reporting module 324.

The first acquisition module 321 is configured to acquire the handling completion record from the first submodule 311.

The second acquisition module 322 is configured to acquire the goods arrival at EQP record from the second submodule 312.

The comparison module 323 is configured to determine whether the handling completion record corresponds to the goods arrival at EQP record by comparing the acquired handling completion record and goods arrival at EQP record.

The exception reporting module 324 is configured to, when the handling completion record does not correspond to the goods arrival at EQP record, generate the exception reporting information and send the exception reporting information to the monitoring platform.

In the embodiment, the handling completion record and the goods arrival at EQP record are compared. When the ID of the destination EQP involved in successful handling in the handling completion record is the same as the EQP ID in the goods arrival at EQP record, and the ID of the handled material is the same as the ID of the material read by the EQP, it is determined that the handling completion record corresponds to the goods arrival at EQP record. Otherwise, it is determined that the compared handling completion record does not correspond to the goods arrival at EQP record.

Specifically, determining whether the handling completion record corresponds to the goods arrival at EQP record one by one by comparing the acquired handling completion record and goods arrival at EQP record is mainly determining whether there is a respective matched goods arrival at EQP record for each handling completion record according to the information of FOUPs in the handling completion record and the goods arrival at EQP record, the information of the FOUP includes the specific position information of the FOUPs, production state information of the FOUPs, and the FOUP IDs. When there is no goods arrival at EQP record matched with one of the handling completion record can be found, it is determined that the EQP corresponding to the handling completion record completes the handling but has not update the information of the FOUP, that is, the EQP has not performed a reading operation currently.

In an embodiment, the fault monitoring system further includes a timing starting module 330. The timing starting module 330 is configured to receive triggering information sent by the MES, trigger, according to the triggering information, the first acquisition module 321 to acquire the handling completion record, start a first timing, and when the duration of the first timing reaches a first preset time interval, trigger the second acquisition module 322 to acquire the goods arrival at EQP record.

In the embodiment, the triggering information is generated by the MES after updating the handling completion record to trigger “watchdog” to be started and acquire the handling completion record from the MES. In addition, since the handling completion record is generated earlier than the goods arrival at EQP record, the EQP that works normally may be reading or reporting the FOUP ID when the handling completion record is read, and the goods arrival at EQP record is required to be acquired after a delay of a period of time. In the disclosure, the timing starting module 330 is arranged to perform the first timing, and when the duration of the first timing reaches the first preset time interval, the goods arrival at EQP record is acquired from the MES, thereby avoiding a false determination caused by untimely updating by the MES. It should be noted that the step of acquiring the handling completion record from the MES may be completed before the step of acquiring the goods arrival at EQP record, or may be executed at the same time with the step of acquiring the goods arrival at EQP record. No limits are made thereto in the embodiment.

In an embodiment, the timing starting module 330 is further configured to, when the comparison module 323 determines that the handling completion record does not correspond to the goods arrival at EQP record, trigger the second acquisition module 322 to retry to acquire the goods arrival at EQP record after a second preset time interval and trigger the comparison module 323 to compare the handling completion record and the acquired goods arrival at EQP record from a retry and determine whether the handling completion record corresponds to the acquired goods arrival at EQP record from a retry until a number of retries reaches a preset number of retries. The exception reporting module is further configured to, when a result of a last determination shows that the handling completion record does not correspond to the goods arrival at EQP record, generate the exception reporting information and send the exception reporting information to the monitoring platform.

Specifically, when the handling completion record does not correspond to the goods arrival at EQP record, a fault monitoring system determines the corresponding EQP that completes material handling but does not update a position or state of the material and the Load Port of the EQP, counts an “inconsistency” of the position or state of the material once, determines the count of the “inconsistency” as the number of retries, and determines whether the number of retries is less than the preset number of retries. If so, the second timing is performed, and when the duration of second timing reaches the second preset time interval, the step of acquiring the goods arrival at EQP record from the second submodule 312 of the storage module 310 of the MES is re-executed. Otherwise, the exception reporting information is generated and sent to the monitoring platform.

After determining the corresponding EQP that completes handling but does not update the state and the Load Port of the EQP, considering that the time for the EQP to read and report the FOUP ID is much less than an interval between two handling tasks, the “watchdog” may, after it is determined that the handling completion record does not correspond to the goods arrival at EQP record one by one, repeatedly acquire the goods arrival at EQP record from the MES at a second preset time interval to confirm whether the problem of no operation after goods arrival at EQP exists as soon as possible and, when determining that the problem of no operation after goods arrival at EQP exists, notify a staff to solve the problem timely. In addition, acquiring the goods arrival at EQP record from the MES only at the second preset time interval may reduce a transmitted data volume and accelerate a determination process.

Moreover, considering that, generally, a material handling period is long but the time of acquiring the goods arrival at EQP record and/or the handling completion record is short, the first time interval is usually much longer than the second time interval.

In an embodiment, a value of the second time interval ranges from 5 to 15 seconds. It should be understood that the value of the second time interval ranges from 5 to 15 seconds, so that the EQP has enough time to read and report the FOUP ID, a false determination caused by excessively short time and a relatively low reading speed of the EQP may be avoided. Furthermore, the problem of no operation after goods arrival at EQP cannot be found timely due to the excessively long time interval is also avoided. In the embodiment, the second time interval is preferably 8, 10, and 12 seconds.

In an embodiment, a value of the preset number of retries ranges from 3 to 8. It should be understood that the handling completion record is generated earlier than the goods arrival at EQP record, so the EQP that works normally may be in the process of reading or reporting the FOUP ID when the handling completion record is read. Thus it may not be determined whether there is no operation after goods arrival at EQP according to one comparison result to avoid a false determination. In the embodiment, the preset number of retries is preferably set to 4, 5, and 6.

In an embodiment, the exception reporting information is sent to the monitoring platform by a mail, a message, or a notification of an AMS to facilitate the staff at the monitoring platform to acquire the specific content of the exception reporting information and to quickly troubleshoot the fault. Furthermore, an alarming device may further be arranged at the monitoring platform, such as an alarm lamp flashes or an alarm horn beeping, to enable the staff at the monitoring platform to acquire the exception information timely. In the embodiment, the exception reporting information may include the EQP ID, the Load Port ID, and the FOUP ID, and in addition, may further include FOUP handling completion time and current state information of the material.

Each technical feature of the abovementioned embodiments may be combined in any number of ways. For the sake of brevity, not all possible combinations of the technical solutions in the abovementioned embodiments are described. However, as long as the combinations of these technical features do not contradict each other, they should be considered to fall within the scope in the specification.

The abovementioned embodiments only express some implementations of the disclosure, which are specifically described in detail, but they should not be understood as a limitation of the scope of the disclosure. It should be noted that for those of ordinary skilled in the art, multiple transformations and improvements can be made without departing from the concept of the disclosure and all of these fall within the scope of protection of the disclosure. Therefore, the protection scope of the disclosure should be subject to the appended claims.

1. A method for monitoring a default in a semiconductor manufacturing process, comprising:
acquiring a handling completion record and a goods arrival at Equipment (EQP) record from a Manufacturing Execution System (MES);
determining whether the handling completion record corresponds to the goods arrival at EQP record by comparing the acquired handling completion record and goods arrival at EQP record; and
when the handling completion record does not correspond to the goods arrival at EQP record, generating exception reporting information and sending the exception reporting information to a monitoring platform.

2. The method of claim 1, wherein the handling completion record comprises at least an Identity document (ID) of a destination EQP and an ID of a handled material in a successful handling; and the goods arrival at EQP record comprises at least an ID of an EQP and an ID of a material read by the EQP.

3. The method of claim 1, wherein the handling completion record is generated and reported to the MES after an Automated Material Handling System (AMHS) performs a corresponding handling operation on a material responsive to a handling request from the MES.

4. The method of claim 1, wherein a destination EQP reports the goods arrival at EQP record to a Tool Control System (TCS) after receiving and reading a handled material, and then the TCS reports the goods arrival at EQP record to the MES.

5. The method of claim 1, wherein acquiring the handling completion record and the goods arrival at EQP record from the MES comprises:
acquiring the handling completion record from a first submodule of a storage module of the MES, and acquiring the goods arrival at EQP record from a second submodule of the storage module of the MES.

6. The method of claim 5, wherein acquiring the handling completion record and the goods arrival at EQP record from the MES further comprises:
receiving triggering information sent by the MES, the triggering information being generated by the MES after the MES receives the handling completion record;
acquiring the handling completion record from the MES according to the triggering information, and starting a first timing; and
when a duration of the first timing reaches a first preset time interval, acquiring the goods arrival at EQP record from the MES.

7. The method of claim 6, wherein when the handling completion record does not correspond to the goods arrival at EQP record, generating the exception reporting information and sending the exception reporting information to the monitoring platform comprises:
when the handling completion record does not correspond to the goods arrival at EQP record, retrying to acquire the goods arrival at EQP after a second preset time interval, and determining whether the handling completion record corresponds to the goods arrival at EQP record until a number of retries reaches a preset number of retries; and
when a result of a last determination shows that the handling completion record does not correspond to the goods arrival at EQP record, generating the exception reporting information and sending the exception reporting information to the monitoring platform.

8. The method of claim 7, wherein a value of the second preset time interval ranges from 5 to 15 seconds.

9. The method of claim 7, wherein a value of the preset number of retries ranges from 3 to 8.

10. The method of claim 9, wherein sending the exception reporting information comprises sending information of a related material and EQP by a mail, a message, or a notification of an Alarm Management System (AMS).

11. A system for monitoring a fault in a semiconductor manufacturing process, comprising:
a processor; and
a memory configured to store processor-executable instructions,
wherein the processor is configured to:
store a handling completion record and a goods arrival at Equipment (EQP) record; and
acquire the handling completion record and the goods arrival at EQP record from a Manufacturing Execution System (MES), determine whether the handling completion record corresponds to the goods arrival at EQP record by comparing the acquired handling completion record and goods arrival at EQP record, and when the handling completion record does not correspond to the goods arrival at EQP record, generate exception reporting information and send the exception reporting information to a monitoring platform.

12. The system for monitoring the fault of claim 11, wherein the processor is further configured to:
store the handling completion record; and
store the goods arrival at EQP record.

13. The system for monitoring the fault of claim 12, wherein the processor is further configured to:
acquire the handling completion record;
acquire the goods arrival at EQP record;
determine whether the handling completion record corresponds to the goods arrival at EQP record by comparing the acquired handling completion record and goods arrival at EQP record; and
when the handling completion record does not correspond to the goods arrival at EQP record, generate the exception reporting information and send the exception reporting information to the monitoring platform.

14. The system for monitoring the fault of claim 13, wherein the handling completion record is generated and reported to the MES after an Automated Material Handling System (AMHS) performs a corresponding handling operation on a material responsive to a handling request from the MES.

15. The system for monitoring the fault of claim 13, wherein a destination EQP reports the goods arrival at EQP record to a Tool Control System (TCS) after receiving and reading a handled material, and then the TCS reports the goods arrival at EQP record to the MES.

16. The system for monitoring the fault of claim 13, wherein the processor is further configured to: receive triggering information sent by the MES, acquire the handling completion record, start a first timing, and when a duration of the first timing reaches a first preset time interval, acquire the goods arrival at EQP record.

17. The system for monitoring the fault of claim 16, wherein the processor is further configured to
when the handling completion record does not correspond to the goods arrival at EQP record, retry to acquire the goods arrival at EQP record after a second preset time interval, and compare the handling completion record and the acquired goods arrival at EQP record from a retry and determine whether the handling completion record corresponds to the acquired goods arrival at EQP record from the retry until a number of retries reaches a preset number of retries; and
when a result of a last determination shows that the handling completion record does not correspond to the goods arrival at EQP record, generate the exception reporting information and send the exception reporting information to the monitoring platform.

18. The system for monitoring the fault of claim 17, wherein a value of the second preset time interval ranges from 5 to 15 seconds.

19. The system for monitoring the fault of claim 17, wherein a value of the preset number of retries ranges from 3 to 8.
